(19) United States
(12) Patent Application Publication
(10) Pub. No.: US 2002/0118511 A1
(43) Pub. Date: Aug. 29, 2002

(54) Heat dissipation device

(76) Inventors: Prateek J. Dujari, Portland, OR (US); Terrance J. Dishongh, Hillsboro, OR (US); Bin Lian, Hillsboro, OR (US); Damion T. Searls, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/796,809

(22) Filed: Feb. 28, 2001

(51) Int. Cl. H05K 7/20

(52) U.S. Cl. 361/703; 361/704; 257/722; 165/185; 174/16.3

(57) ABSTRACT

A heat dissipation device comprising a base portion, having a chamber defined therein, and a plurality of projections extending from the base portion. At least one projection of the plurality of projections also has a chamber defined therein that is in fluid communication with the base portion chamber to form a vapor chamber of a heat pipe.

### BACKGROUND OF THE INVENTION

1. Field of the Invention

The present invention relates to apparatus and methods for removal of heat from electronic devices. In particular, the present invention relates to a heat dissipation device having at least one hollow projection connected to a chamber in a base portion of the heat dissipation device, wherein the hollow portions of the projections and base portion chamber comprise a heat pipe vapor chamber.

2. State of the Art

Higher performance, lower cost, increased miniaturization of integrated circuit components, and greater packaging density of integrated circuits are ongoing goals of the computer industry. As these goals are achieved, microelectronic dice become smaller. Accordingly, the density of power consumption of the integrated circuit components in the microelectronic die has increased, which, in turn, increases the average junction temperature of the microelectronic die. If the temperature of the microelectronic die becomes too high, the integrated circuits of the microelectronic die may be damaged or destroyed.

Various apparatus and techniques have been used and are presently being used for removing heat from microelectronic dice. One such heat dissipation technique involves the attachment of a high surface area heat sink to a microelectronic die. FIG. 5 illustrates an assembly 200 comprising a microelectronic die 202 (illustrated as a flip chip) physically and electrically attached to a substrate carrier 204 by a plurality of solder balls 206. A heat sink 208 is attached to a back surface 212 of the microelectronic die 202 by a thermally conductive adhesive 214. The heat sink 208 is usually constructed from a thermally conductive material, such as copper, copper alloys, aluminum, aluminum alloys, and the like. The heat generated by the microelectronic die 202 is drawn into the heat sink 208 (following the path of least thermal resistance) by conductive heat transfer.

High surface area heat sinks 208 are generally used because the rate at which heat is dissipated from a heat sink is substantially proportional to the surface area of the heat sink. The high surface area heat sink 208 usually includes a plurality of projections 216 extending substantially perpendicularly from the microelectronic die 202. It is, of course, understood that the projections 216 may include, but are not limited to, elongate planar fin-like structures and columnar/pillar structures. The high surface area of the projections 216 allows heat to be convectively dissipated from the projections 216 into the air surrounding the high surface area heat sink 208. A fan 218 may be incorporated into the assembly 200 to enhance the convective heat dissipation. However, although high surface area heat sinks are utilized in a variety of microelectronic applications, they have not been completely successful in removing heat from microelectronic dice that generate substantial amounts of heat.

Another known method of removing heat from a microelectronic die is the use of a heat pipe 220, as shown in FIG. 6. A heat pipe 220 is a simple device that can quickly transfer heat from one point to another without the use of electrical or mechanical energy input. The heat pipe 220 is generally formed by evacuating air from a sealed pipe 222 that contains a “working fluid” 224, such as water or alcohol. The sealed pipe 222 is oriented with a first end 226 proximate a heat source 228. The working fluid 224, which is in a liquid phase proximate the heat source 228, increases in temperature and evaporates to form a gaseous phase of the working fluid 224, which moves (shown by arrows 232) toward a second end 234 of the sealed pipe 222. As the gaseous phase moves toward the sealed pipe second end 234, it condenses to again form the liquid phase of the working fluid 224, thereby releasing the heat absorbed during the evaporation of the liquid phase of the working fluid 224. The liquid phase returns, usually by capillary action or gravity, to the sealed pipe first end 226 proximate the heat source 228, wherein the process is repeated. Thus, the heat pipe 220 is able to rapidly transfer heat away from the heat source 228.

Various configurations of heat pipes have been used to cool microelectronic dice and they have been used in conjunction with finned heat slugs 202. However, such configurations have not been entirely successful, and using cryogenic cooling or refrigeration cooling are unviable options for a high volume microelectronic device to stay competitively priced.

Therefore, it would be advantageous to develop apparatus to effectively remove heat from microelectronic dice.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings to which:

FIG. 1 is a side cross-sectional view of an embodiment of a heat dissipation device attached to a microelectronic die, according to the present invention;

FIG. 2 is an oblique view of a cross-section of an embodiment of a heat dissipation device, according to the present invention;

FIG. 3 is an oblique view of a cross-section of another embodiment of a heat dissipation device, according to the present invention;

FIG. 4 is a side cross-sectional view of still another embodiment of a heat dissipation device attached to a microelectronic die, as known in the art.

FIG. 5 is a side cross-sectional view of a heat dissipation device attached to a microelectronic die, as known in the art; and

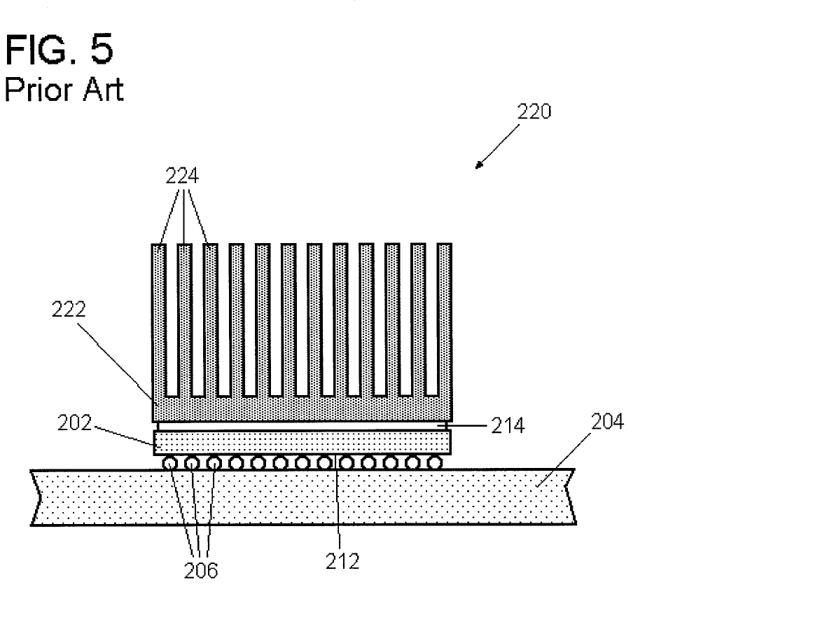

FIG. 6 is a side cross-sectional view of a heat pipe, as known in the art.

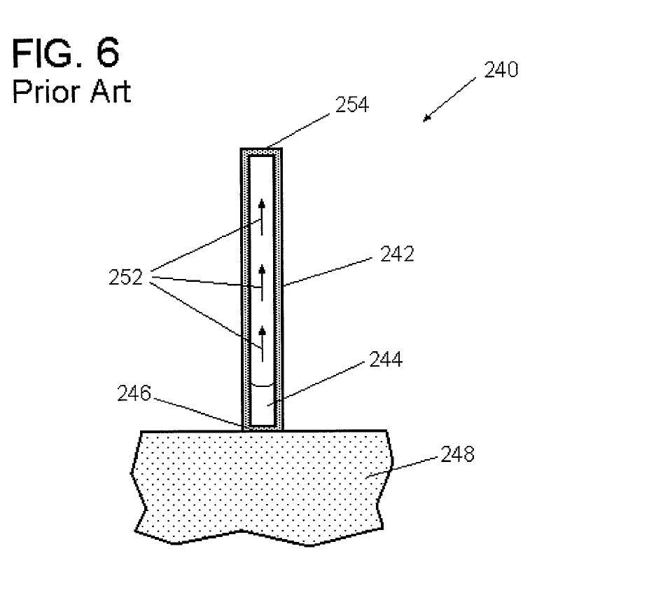

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable though skilled in the art to practice the invention. It is to be understood that the various embodiments of the invention, although different, are not necessarily mutually exclusive. For example, a particular feature, structure, or characteristic described herein, in connection with one embodiment, may be implement within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention comprises a heat dissipation device that includes a base portion, having a chamber defined therein, and a plurality of projections extending from the base portion. At least one projection of the plurality of projections also has a chamber defined therein that is in fluid communication with the base portion chamber to form a vapor chamber of a heat pipe.

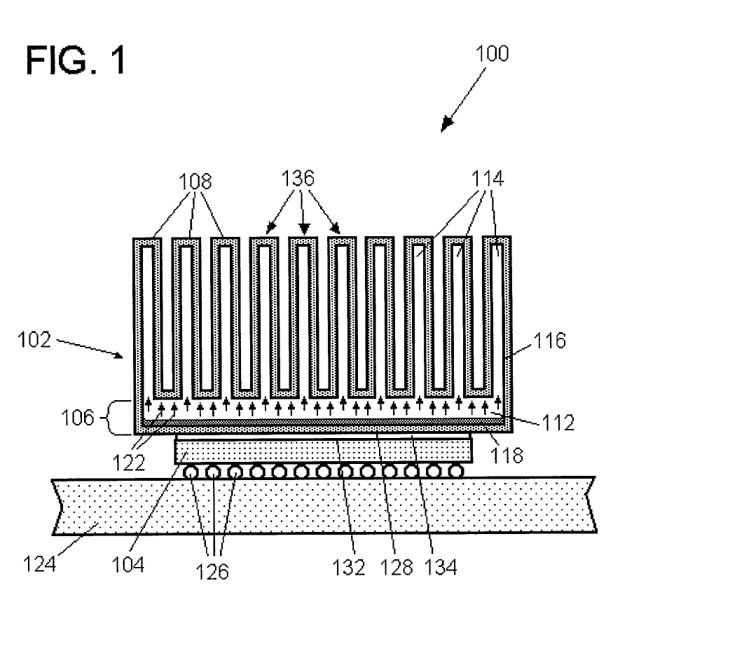

FIG. 1 illustrates a microelectronic assembly 100 of the present invention comprising a heat dissipation device 102 attached to a microelectronic die 104 (illustrated as a flip chip). The heat dissipation device 102 includes a base portion 106 having a plurality of projections 108, preferably extending substantially perpendicularly therefrom. The heat dissipation device base portion 106 includes a chamber 112 formed therein. The plurality of projections 108 also includes chambers 114 formed therein, which are in fluid communication with the base portion chamber 112. The each of the plurality of projections 108 is preferably substantially hollow. The combination of the base portion chamber 112 and the projections chambers 114 form a vapor chamber of a heat pipe that will be hereinafter referred to as vapor chamber 116. The vapor chamber 116 is, of course, sealed and contains a working fluid 118, such as water or alcohol. The vapor chamber 116 is preferably under a low-pressure atmosphere or partial vacuum. The heat dissipation device 102 is preferably constructed from a thermally conductive material, such as copper, copper alloys, aluminum, aluminum alloys, and the like.

As previously discussed, the working fluid 118 is generally in a liquid phase proximate the heat source, i.e., the microelectronic die 104. As the microelectronic die 104 heats under normal operation, the temperature of the working fluid 118 within the vapor chamber 116 is increased, resulting in the evaporation of the working fluid 118 to form a gaseous phase. As the gaseous phase moves toward and into the projection chambers 114 of the vapor chamber 116 (illustrated with arrows 122), it condenses to again form the liquid phase of the working fluid 118, thereby releasing the heat absorbed during the evaporation of the liquid phase of the working fluid 118. The liquid phase returns by condensing and trickling down the interior walls of the projection chambers 114, by gravity or by capillary action, to the base portion chamber 112 of the vapor chamber 116 proximate the microelectronic die 104, wherein the process is repeated. Thus, the vapor chamber 116 is able to rapidly transfer heat away from the microelectronic die 104 to the plurality of projections 108 for dissipation of the heat to the surrounding air. The projection chambers 114 may include an interior lining (not shown) to assist in the condensation and return of the working fluid 118, as will be understood by those skilled in the art. It is understood that depending on the amount of heat to be removed, all or just some of the projections 108 may have projection chambers 114.

The projection chambers 114 may be formed by conventional techniques, such as drilling holes in the projections 108 on a multiple spindle machine from a first surface 136 of the projections 108 through to the base portion chamber 112, and then capping the hole proximate the projection first surface 136 by welding, brazing, or other otherwise attaching an appropriately sized cap of the same or similar material from which the heat dissipation device 102 is made. The entire heat dissipation device 102 (hollow projections and hollow base portion) may be formed by injection molding and other such fabrication techniques as will be evident to one skilled in the art.

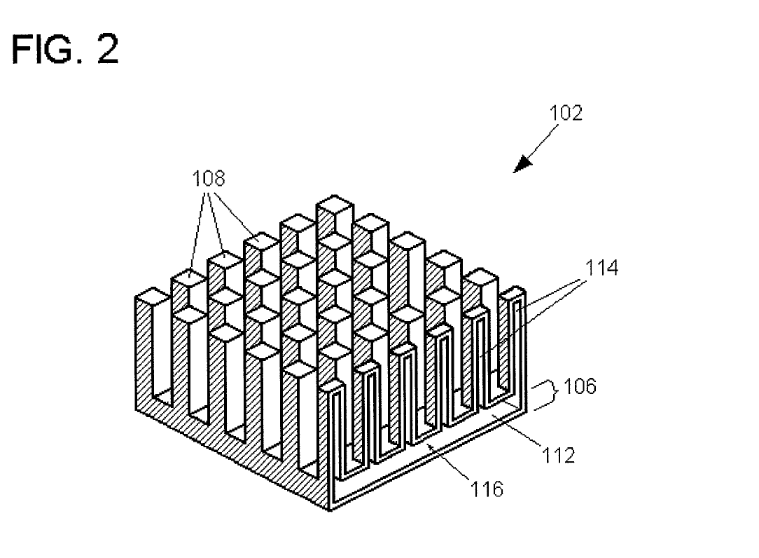

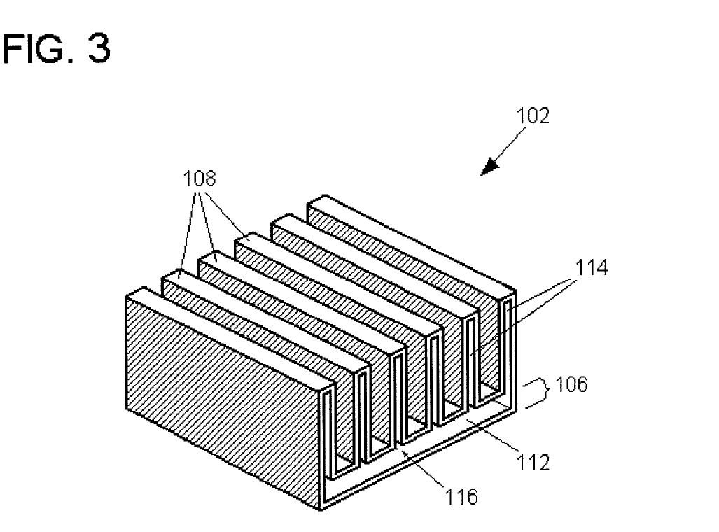

It is, of course, understood that the projections 108 may include, but are not limited to, column/pillar-type structures, such as shown in FIG. 2, and elongate planar fin-like structures, such as shown in FIG. 3.

The microelectronic die 104 is physically and electrically attached to a substrate 124 by a plurality of solder balls 126. A mounting surface 128 of the heat dissipation device base portion 106 is attached to a back surface 132 of the microelectronic die 104, preferably by a thermally conductive adhesive 134 as known in the art. Although the heat dissipation device 102 is illustrated as being attached to the microelectronic die 104, the invention is, of course, not so limited. The heat dissipation device 102 may be attached to any surface from which heat is desired to be dissipated.

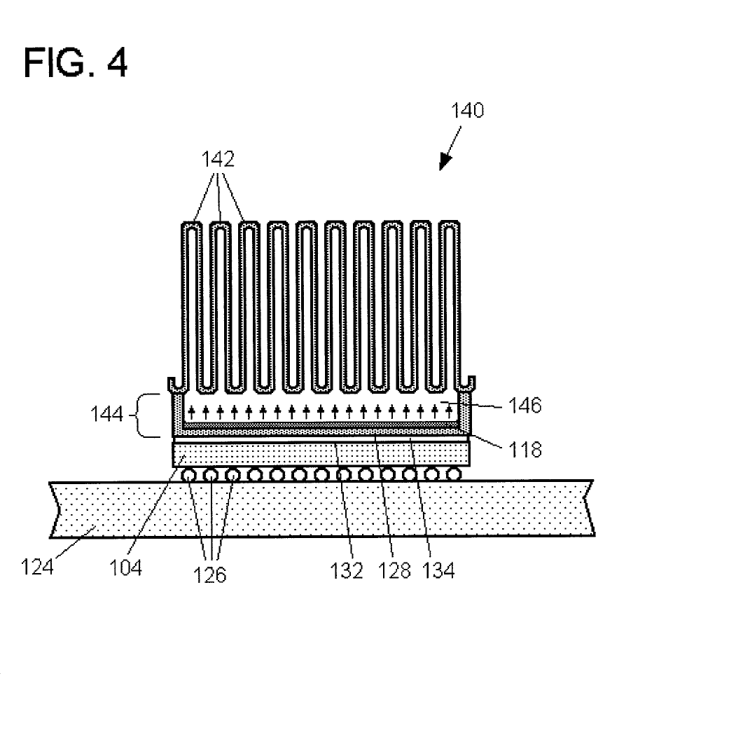

FIG. 4 illustrates another embodiment of a heat dissipation device 140 of the present invention incorporating a plurality of folded-fin projections 142. The plurality of folded-fin projections 142 are formed from a flat stock conductive sheet, such as a thermal plastic or metal, preferably copper, copper alloys, aluminum, aluminum alloys, or the like. The plurality of folded-fin projections 142 are formed by folding the flat stock conductive sheet in an “accordion-like” or “wave-like” fashion, as illustrated in FIG. 4. Such folded-fin projections 142 are particularly advantageous because they can be formed more cheaply and more conveniently than machined or molded finned heat sinks. The folded-fin projections 142 are attached to a base plate 144, having a recess 146 formed therein, preferably by application of solder, epoxy, or the like (not shown). The base plate chamber 146 is open in the direction of the folded-fin projections 142, such that they are in fluid communication. The working fluid 118 is disposed in the base plate recess 146 and the assembly is sealed (preferably under a low-pressure atmosphere or partial vacuum).

It is, of course, understood that the integration of hollow projections, as discussed above, can potentially require a larger cross-section of the projections. However, as the projections are hollow, the cross sectional area can be adjusted in order to ensure no appreciable increase in the overall weight of the heat dissipation device results.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A heat dissipation device, comprising:
a base portion having at least one chamber defined therein;
a plurality of projections extending from said base portion, at least one of said plurality of projections having at least one chamber defined therein; and
said base portion chamber and said at least one projection chamber adapted to be in fluid communication with one another to form a vapor chamber.

2. The heat dissipation device of claim 1, further including a working fluid disposed within said vapor chamber.

3. The heat dissipation device of claim 1, wherein said plurality of projections comprise a plurality of pillars.

4. The heat dissipation device of claim 1, wherein said plurality of projections comprise a plurality of fins.

5. The heat dissipation device of claim 1, wherein said plurality of projections comprise a plurality of folded-fin projections.

6. The heat dissipation device of claim 1, wherein said base portion and said plurality of projections comprise a metal.

7. A microelectronic assembly, comprising:
a microelectronic die having a back surface; and
a heat dissipation device attached to said microelectronic die back surface, comprising:
a base portion having at least one chamber defined therein;
a plurality of projections extending from said base portion, at least one of said plurality of projections having a chamber defined therein; and
said base portion chamber and said at least one projection chamber adapted to be in fluid communication with one another to form a vapor chamber.

8. The microelectronic assembly of claim 7, further including a working fluid disposed within said vapor chamber.

9. The microelectronic assembly of claim 7, wherein said plurality of projections comprise a plurality of pillars.

10. The microelectronic assembly of claim 7, wherein said plurality of projections comprise a plurality of fins.

11. The microelectronic assembly of claim 7, wherein said plurality of projections comprise a plurality of folded-fin projections.

12. The microelectronic assembly of claim 7, wherein said base portion and said plurality of projections comprise a metal.

13. A method of forming a heat dissipation device, comprising:
forming a heat dissipation device base portion having at least one chamber defined therein;
forming a plurality of projections extending from said base portion;
drilling a hole in at least one of said plurality of projections, wherein said hole extends from a first surface to said at least one base portion chamber; and
capping said hole proximate said projection first surface.

14. The method of claim 13, further including disposing a working fluid within said base portion chamber.

15. The method of claim 13, wherein forming said plurality of projections comprises forming a plurality of pillars.

16. The method of claim 13, wherein forming said plurality of projections comprises forming a plurality of fins.

17. A method of forming a heat dissipation device, comprising:
forming a heat dissipation device base portion having at least one recess defined therein;
forming a plurality of folded-fin projections;
attaching said folded-fin projections to said base portion; and
sealing said folded-fin projections to form a vapor chamber from said base portion recess and said sealed folded-fin projections.

18. The method of claim 17, further including disposing a working fluid within said vapor chamber.

19. The method of claim 17, wherein said forming a plurality of folded-fin projections comprises folding a flat stock metal sheet to form a plurality of folded-fin projections.

20. The method of claim 17, wherein said forming a plurality of folded-fin projections comprises folding a flat stock conductive, thermal plastic sheet to form a plurality of folded-fin projections.
